(19) United States
(12) Patent Application Publication
(10) Pub. No.: US 2025/0148983 A1
(43) Pub. Date: May 8, 2025

(54) LIGHT EMITTING DEVICE, DISPLAY DEVICE, PHOTOELECTRIC CONVERSION DEVICE, ELECTRONIC APPARATUS, ILLUMINATION DEVICE, AND MOVING BODY

(71) Applicant: CANON KABUSHIKI KAISHA, Tokyo (JP)

(72) Inventor: TETSURO YAMAMOTO, Kanagawa (JP)

(21) Appl. No.: 18/928,501

(22) Filed: Oct. 28, 2024

(30) Foreign Application Priority Data
Nov. 6, 2023 (JP) 2023-189527

(51) Int. Cl. G09G 3/3233; H01L 25/16; H04N 23/63

(52) U.S. Cl. CPC G09G 3/3233; H04N 23/63; G09G 2300/0819; G09G 2300/0842; G09G 2310/0286; G09G 2310/08; H01L 25/167

(57) ABSTRACT

Alight emitting device includes a light emitting element, a driving transistor and a switching transistor each arranged on a path where a current for causing the light emitting element to emit light flows, a writing transistor arranged on a path connecting a signal line to which a pixel signal is supplied and a gate of the driving transistor, and a holding transistor configured to hold a gate-source voltage of the driving transistor. Agate of the holding transistor is connected to the gate of the driving transistor. Each of a source and a drain of the holding transistor is connected to a source of the driving transistor. The holding transistor and the switching transistor are formed in a same impurity region. A conductivity type of the holding transistor is the same as a conductivity type of the driving transistor.

### BACKGROUND OF THE INVENTION

### Field of the Invention

The present invention relates to a light emitting device, a display device, a photoelectric conversion device, an electronic apparatus, an illumination device, and a moving body.

### Description of the Related Art

An active matrix display device in which a driving transistor for controlling a current flowing to a light emitting element is arranged in a pixel circuit is under development. The pixel circuit of a display device described in Japanese Patent Laid-Open No. 2010-145579 includes a capacitive element connecting the source and gate of a driving transistor and another capacitive element connecting the source of the driving transistor and a power supply line. International Publication No. 2018/020844 describes a technique for forming one of two capacitive elements in a pixel circuit in a semiconductor substrate. If a particular function provided by the pixel circuit can be implemented with fewer elements, this can lead to pixel size reduction and cost reduction.

### SUMMARY OF THE INVENTION

An aspect of the present disclosure reduces the number of elements in a pixel circuit for providing a particular function. According to some embodiments, a light emitting device comprising: a light emitting element; a driving transistor and a switching transistor each arranged on a path where a current for causing the light emitting element to emit light flows; a writing transistor arranged on a path connecting a signal line to which a pixel signal is supplied and a gate of the driving transistor; and a holding transistor configured to hold a gate-source voltage of the driving transistor, wherein a gate of the holding transistor is connected to the gate of the driving transistor, each of a source and a drain of the holding transistor is connected to a source of the driving transistor, the holding transistor and the switching transistor are formed in a same impurity region, and a conductivity type of the holding transistor is the same as a conductivity type of the driving transistor is provided.

Further features of the present invention will become apparent from the following description of exemplary embodiments with reference to the attached drawings.

### BRIEF DESCRIPTION OF THE DRAWINGS

FIG. 1 is a block diagram for explaining an example of the arrangement of a light emitting device according to the first embodiment;

FIG. 2 is a circuit diagram for explaining an example of the arrangement of a pixel circuit according to the first embodiment;

FIG. 3 is a schematic sectional view for explaining an example of the arrangement of a holding transistor according to the first embodiment;

FIG. 4 is a circuit diagram for explaining an equivalent circuit of the pixel circuit according to the first embodiment;

FIG. 5 is a timing chart for explaining an example of the operation of the light emitting device according to the first embodiment;

FIGS. 6A to 6F are circuit diagrams for explaining the example of the operation of the light emitting device according to the first embodiment;

FIG. 7 is a circuit diagram for explaining the arrangement of a pixel circuit according a comparative example;

FIG. 8 is a schematic sectional view for explaining the arrangement of a holding transistor according to the comparative example;

FIG. 9 is a circuit diagram for explaining an example of the arrangement of the pixel circuit according to the first embodiment;

FIGS. 10A and 10B are schematic views for explaining a layout example of transistors according to the first embodiment;

FIG. 11 is a circuit diagram for explaining a modification of the pixel circuit according to the first embodiment;

FIG. 12 is a circuit diagram for explaining a modification of the pixel circuit according to the first embodiment;

FIG. 13 is a block diagram for explaining an example of the arrangement of a light emitting device according to the second embodiment;

FIG. 14 is a circuit diagram for explaining an example of the arrangement of a pixel circuit according to the second embodiment;

FIG. 15 is a circuit diagram for explaining an example of the arrangement of the pixel circuit according to the second embodiment;

FIG. 16 is a schematic view for explaining a layout example of transistors according to the second embodiment;

FIG. 17 is a view showing an example of a display device using the light emitting device according to the embodiment;

FIG. 18A is a view showing an example of a photoelectric conversion device using the light emitting device according to the embodiment;

FIG. 18B is a view showing an example of an electronic apparatus using the light emitting device according to the embodiment;

FIGS. 19A and 19B are views each showing an example of a display device using the light emitting device according to the embodiment;

FIG. 20A is a view showing an example of an illumination device using the light emitting device according to the embodiment;

FIG. 20B is a view showing an example of a moving body using the light emitting device according to the embodiment; and

FIGS. 21A and 21B are views each showing an example of a wearable device using the light emitting device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

### First Embodiment

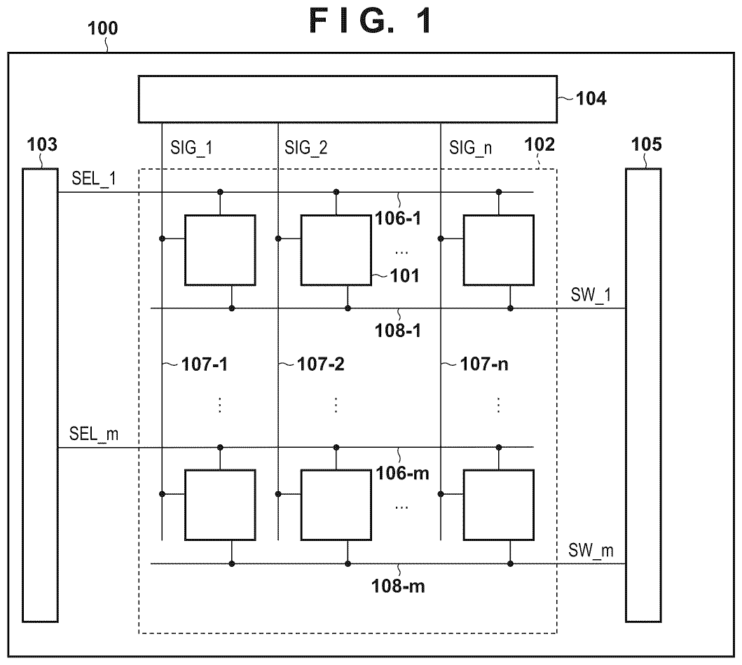

With reference to FIG. 1, an example of the arrangement of a light emitting device 100 according to the first embodiment will be described. As will be described later, the light emitting device 100 may be used in a display device. For example, the light emitting device 100 may be used in a flat type (or flat panel type) display device. Numerical values, shapes, materials, the types of constituent elements, and the arrangements and connection forms of the constituent elements used in the description of an embodiment are merely examples and not intended to limit the present invention.

The light emitting device 100 may include a plurality of pixel circuits 101, a write scanning circuit 103, a signal output circuit 104, and a light emission scanning circuit 105. The plurality of pixel circuits 101 are arranged in a two-dimensional array (that is, to form a plurality of rows and a plurality of columns) in a pixel array portion 102. Instead, the plurality of pixel circuits 101 may be arranged in a one-dimensional array. In the example shown in FIG. 1, the plurality of pixel circuits 101 are arranged in m rows and n columns (m and n are integers equal to or larger than 1). The pixel circuit 101 may be simply referred to as a pixel.

The write scanning circuit 103, the signal output circuit 104, and the light emission scanning circuit 105 are arranged around the pixel array portion 102. The write scanning circuit 103, the signal output circuit 104, and the light emission scanning circuit 105 are examples of circuits forming the driving unit of the light emitting device 100. The write scanning circuit 103 and the light emission scanning circuit 105 form a scan-driving system. The signal output circuit 104 forms a signal supply system. In the layout shown in FIG. 1, the write scanning circuit 103 is arranged on the left side of the pixel array portion 102, and the light emission scanning circuit 105 is arranged on the right side of the pixel array portion 102. Instead, another layout may be used. For example, the arrangements of the write scanning circuit 103 and the light emission scanning circuit 105 with respect to the pixel array portion 102 may be reversed from the example shown in FIG. 1, or the write scanning circuit 103 and the light emission scanning circuit 105 may be arranged on the same side with respect to the pixel array portion 102. Alternatively, a layout may be used in which the write scanning circuits 103 and the light emission scanning circuits 105 are arranged on each of the left and right sides of the pixel array portion 102.

One pixel of an image displayed by the light emitting device 100 may be displayed by one pixel circuit 101, or may be displayed by multiple pixel circuits 101. When one pixel of an image is displayed by multiple pixel circuits 101, this pixel may be referred to include a plurality of sub-pixels. Each of the plurality of sub-pixels may be displayed by one pixel circuit 101. For example, one pixel may be formed by three sub-pixels of a sub-pixel which emits red (R) light, a sub-pixel which emits green (G) light, and a sub-pixel which emits blue (B) light. Instead, one pixel may be formed by sub-pixels of three primary colors and one or more sub-pixels of other colors. One or more sub-pixels of other colors may include a sub-pixel which emits white (W) light to improve luminance, or may include one or more sub-pixels which emit light of complementary colors to expand the color reproduction range.

In the pixel array portion 102, m write scanning lines 106-1 to 106-m and m light emission scanning lines 108-1 to 108-m are arranged along pixel rows (that is, rows each formed by multiple pixels arranged in the horizontal direction in FIG. 1). In the pixel array portion 102, n signal lines 107-1 to 107-n are arranged along pixel columns (that is, columns each formed by multiple pixels arranged in the vertical direction in FIG. 1). In the following description, the m write scanning lines 106-1 to 106-m are collectively referred to as write scanning lines 106. A description of the write scanning line 106 may apply to any of one or more write scanning lines 106-1 to 106-m. The write scanning line 106 may represent an arbitrary one of one or more write scanning lines 106-1 to 106-m, or a specific one which is determined by the context. This also applies to other constituent elements to be collectively referred to below. The m light emission scanning lines 108-1 to 108-m are collectively referred to as light emission scanning lines 108, and the n signal lines 107-1 to 107-n are collectively referred to as signal lines 107. One write scanning line 106 and one light emission scanning line 108 may be arranged for one pixel row. One signal line 107 may be arranged for one pixel column.

The write scanning line 106 is connected to the corresponding output terminal of m output terminals of the write scanning circuit 103. The light emission scanning line 108 is connected to the corresponding output terminal of m output terminals of the light emission scanning circuit 105. The signal line 107 is connected to the corresponding output terminal of n output terminals of the signal output circuit 104.

The signal output circuit 104 supplies pixel signals SIG_1 to SIG_n to the n signal lines 107. In the following description, the n pixel signals SIG_1 to SIG_n are collectively referred to as pixel signals SIG. The pixel signal SIG can have a signal potential Vsig corresponding to luminance information supplied from a signal supply source (not shown). The signal potentials Vsig output from the signal output circuit 104 are written in multiple pixel circuits 101 on a row basis via the signal lines 107. Such writing may be referred to as line sequential writing.

The write scanning circuit 103 is formed by a shift register, which sequentially shifts a start pulse in synchronization with a clock pulse, or the like. When writing the pixel signals SIG in respective pixel circuits 101, the write scanning circuit 103 supplies write scanning signals SEL_1 to SEL_m to the m write scanning lines 106 to sequentially scan the plurality of pixel circuits 101 on a row basis. Such scanning may be referred to as line sequential scanning. In the following description, the m write scanning signals SEL_1 to SEL_m are collectively referred to as write scanning signals SEL. The pixel signal SIG may be called an image signal when the light emitting device 100 displays an image, and may be called a video signal when the light emitting device 100 displays a video.

The light emission scanning circuit 105 is formed by a shift register, which sequentially shifts a start pulse in synchronization with a clock pulse, or the like. The light emission scanning circuit 105 supplies light emission scanning signals SW_1 to SW_m to the m light emission scanning lines 108 in synchronization with line sequential scanning by the write scanning circuit 103, thereby controlling each pixel circuit 101 to emit light or not. In the following description, the m light emission scanning signals SW_1 to SW_m are collectively referred to as light emission scanning signals SW.

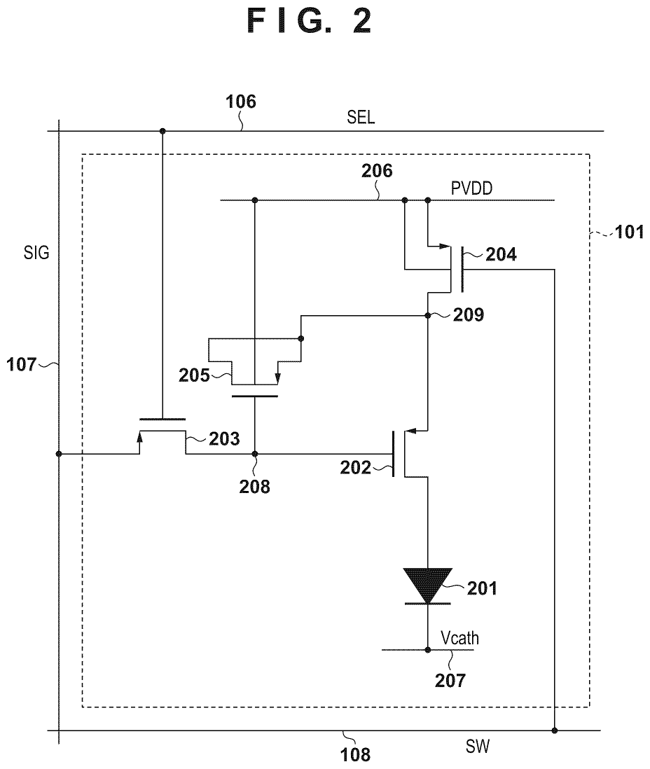

With reference to FIG. 2, an example of the arrangement of the pixel circuit 101 will be described. The pixel circuit 101 may include a light emitting element 201, a driving transistor 202, a writing transistor 203, a switching transistor 204, and a holding transistor 205. The light emitting element 201 may be a current-driven electro-optical element whose light emission luminance changes in accordance with the amount of current flowing through the light emitting element 201. The light emitting element 201 may be, for example, a light emitting diode (LED) or an organic electroluminescence (EL) element. The driving transistor 202, the writing transistor 203, the switching transistor 204, and the holding transistor 205 form a drive circuit for driving the light emitting element 201. The light emitting element 201 may include an anode and a cathode. The cathode of the light emitting element 201 is connected to a light supply line 207. The power supply line 207 is commonly arranged for the plurality of pixel circuits 101. A potential Vcath is supplied to the power supply line 207. All the transistors included in the pixel circuit 101 may be p-channel transistors. Instead, some or all of the transistors included in the pixel circuit 101 may be n-channel transistors.

The driving transistor 202 may be, for example, a p-channel transistor. The conductivity type of the holding transistor 205 may be the same as the conductivity type of the driving transistor 202 (for example, both may be p-channel). The holding transistor 205 and the switching transistor 204 may be formed on the same semiconductor substrate. Further, the holding transistor 205 and the switching transistor 204 may be formed in the same n-type impurity region (for example, well region) formed on a p-type semiconductor substrate. Instead, the holding transistor 205 and the switching transistor 204 may be formed in an n-type impurity region which is a part of an n-type semiconductor substrate.

The driving transistor 202 is a transistor configured to adjust the amount of current flowing through the light emitting element 201. The current flowing through the light emitting element 201 can also be called a driving current. Since the light emitting element 201 emits light when a driving current flows therethrough, the driving current is a current that causes the light emitting element 201 to emit light. The driving transistor 202 is arranged on a path where the driving current flows (in the example shown in FIG. 2, on a path from a power supply line 206 to the power supply line 207 through the switching transistor 204, the driving transistor 202, and the light emitting element 201). In the example shown in FIG. 2, the driving transistor 202 is arranged on a path connecting the light emitting element 201 and the switching transistor 204. The driving transistor 202 is connected to the light emitting element 201 in series. In the example shown in FIG. 2, one (for example, drain) of two main terminals of the driving transistor 202 is connected to the anode of the light emitting element 201.

The writing transistor 203 is a transistor configured to switch whether to write, in the gate of the driving transistor, the pixel signal supplied from the signal output circuit 104 to the pixel circuit 101 via the signal line 107. The writing transistor 203 is arranged on a path connecting the signal line 107 and the gate of the driving transistor 202. The gate of the writing transistor 203 is connected to the write scanning line 106. One (for example, source) of two main terminals of the writing transistor 203 is connected to the signal line 107. The other (for example, drain) of two main terminals of the writing transistor 203 is connected to the gate of the driving transistor 202. The write scanning signal SEL is supplied to the gate of the writing transistor 203 from the write scanning circuit 103 via the write scanning line 106.

The switching transistor 204 is a transistor configured to switch whether to cause the light emitting element 201 to emit light. The switching transistor 204 is arranged on the path where the driving current flows. In the example shown in FIG. 2, the switching transistor 204 is arranged on a path connecting the source of the driving transistor 202 and the power supply line 206. The gate of the switching transistor 204 is connected to the light emission scanning line 108. One (for example, source) of two main terminals of the switching transistor 204 is connected to the power supply line 206. A positive power supply potential PVDD is supplied to the power supply line 206. The power supply potential PVDD supplied to the power supply line 206 may be higher than the potential Vcath supplied to the power supply line 207. The other (for example, drain) of two main terminals of the switching transistor 204 is connected to the main terminal (for example, source) not connected to the light emitting element 201 among two main terminals of the driving transistor 202. The back gate of the switching transistor 204 is connected to the power supply line 206. The light emission scanning signal SW is supplied to the gate of the switching transistor 204 from the light emission scanning circuit 105 via the light emission scanning line 108.

The holding transistor 205 is a transistor configured to hold the gate-source voltage of the driving transistor 202. The gate of the holding transistor 205 is connected to the gate of the driving transistor 202. Each of two main terminals (for example, source and drain) of the holding transistor 205 is connected to the main terminal (for example, source) not connected to the light emitting element 201 among two main terminals of the driving transistor 202. The back gate of the holding transistor 205 is connected to the power supply line 206. That is, the back gate of the holding transistor 205 and the source of the switching transistor 204 are connected to the same power supply line 206.

As has been described above, in the circuit arrangement shown in FIG. 2, the gate of the driving transistor 202, one main terminal (for example, drain) of the writing transistor 203, and the gate of the holding transistor 205 are connected to the same node 208. One main terminal (for example, source) of the driving transistor 202, one main terminal (for example, drain) of the switching transistor 204, and each of two main terminals (for example, source and drain) of the holding transistor 205 are connected to the same node 209.

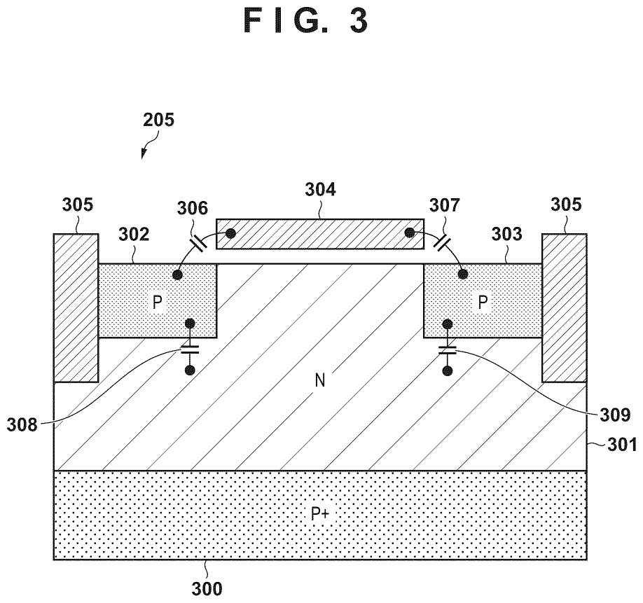

Next, with reference to FIG. 3, an example of the arrangement of the holding transistor 205 will be described. FIG. 3 is a sectional view of the holding transistor 205. The holding transistor 205 is formed in an n-type well region 301 formed on a p-type substrate 300. The well region 301 is a well-type impurity region used as the substrate conductive layer of a CMOS (Complementary Metal-Oxide-Semiconductor) transistor. P-type impurity regions 302 and 303 are formed in the well region 301. The impurity regions 302 and 303 can also be called impurity diffusion regions or diffusion regions. Agate electrode 304 is formed to cover a portion of the well region 301 between the impurity region 302 and the impurity region 303. Agate insulating film (not shown) is formed between the gate electrode 304 and the well region 301. Element isolation portions 305 are formed outside the impurity regions 302 and 303.

The impurity region 302 functions as one (for example, source) of two main terminals of the holding transistor 205. The impurity region 303 functions as the other (for example, drain) of two main terminals of the holding transistor 205. The gate electrode 304 functions as the gate of the holding transistor 205. The power supply potential PVDD is supplied to the well region 301 from the power supply line 206 via a well contact (not shown).

A capacitance 306 is formed between the impurity region 302 and the gate electrode 304. A capacitance 307 is formed between the impurity region 303 and the gate electrode 304. A capacitance 308 is formed between the impurity region 302 and the well region 301. A capacitance 309 is formed between the impurity region 303 and the well region 301. In this manner, a plurality of capacitances are formed by the holding transistor 205.

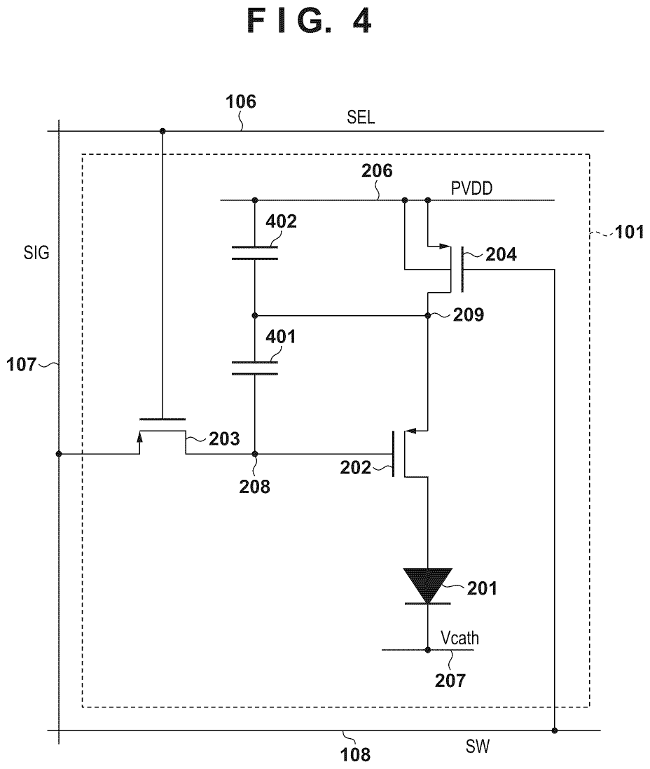

With reference to FIG. 4, an equivalent circuit of the pixel circuit 101 shown in FIG. 2 will be described. Since the impurity regions 302 and 303 function as two main terminals of the holding transistor 205, the impurity regions 302 and 303 are connected to the node 209. Since the gate electrode 304 functions as the gate of the holding transistor 205, the gate electrode 304 is connected to the node 208. Accordingly, the capacitance 306 and the capacitance 307 are combined and become a capacitance 401 connecting the node 208 and the node 209 (that is, connecting the gate and source of the driving transistor 202). Since the well region 301 functions as the back gate of the holding transistor 205, the well region 301 is connected to the power supply line 206. Accordingly, the capacitance 308 and the capacitance 309 are combined and become a capacitance 402 connecting the power supply line 206 and the node 209. In this manner, one holding transistor 205 functions as two capacitances 401 and 402.

The writing transistor 203 is switched between a conductive state and a non-conductive state in accordance with the write scanning signal SEL. When the writing transistor 203 is in the conductive state, the pixel signal SIG supplied from the signal output circuit 104 via the signal line 107 is supplied to the gate of the driving transistor 202, and the pixel signal SIG is held by the capacitance 401 of the holding transistor 205. The pixel signal SIG is set to have two values of a reference potential Vcal and the signal potential Vsig in one horizontal period. The signal potential Vsig can be a value corresponding to luminance information.

The switching transistor 204 is switched between a conductive state and a non-conductive state in accordance with the light emission scanning signal SW. When the switching transistor 204 is in the conductive state, a current flows from the power supply line 206 to the driving transistor 202. With this, the driving transistor 202 can cause the light emitting element 201 to emit light. More specifically, the driving transistor 202 supplies, to the light emitting element 201, a driving current corresponding to the signal potential Vsig held by the capacitance 401 of the holding transistor 205. This driving current causes the light emitting element 201 to emit light. When the switching transistor 204 is in the non-conductive state, no current flows from the power supply line 206 to the driving transistor 202. Accordingly, the driving transistor 202 cannot cause the light emitting element 201 to emit light.

The light emitting device 100 can control the ratio of the light emission period and the non-light emission period of the light emitting element 201 by the switching operation of the switching transistor 204. Such control can be called duty control. The duty control can reduce an afterimage generated when the pixel circuit 101 emits light over one frame period. This improves the quality of an image (particularly, moving image) displayed by the light emitting device 100.

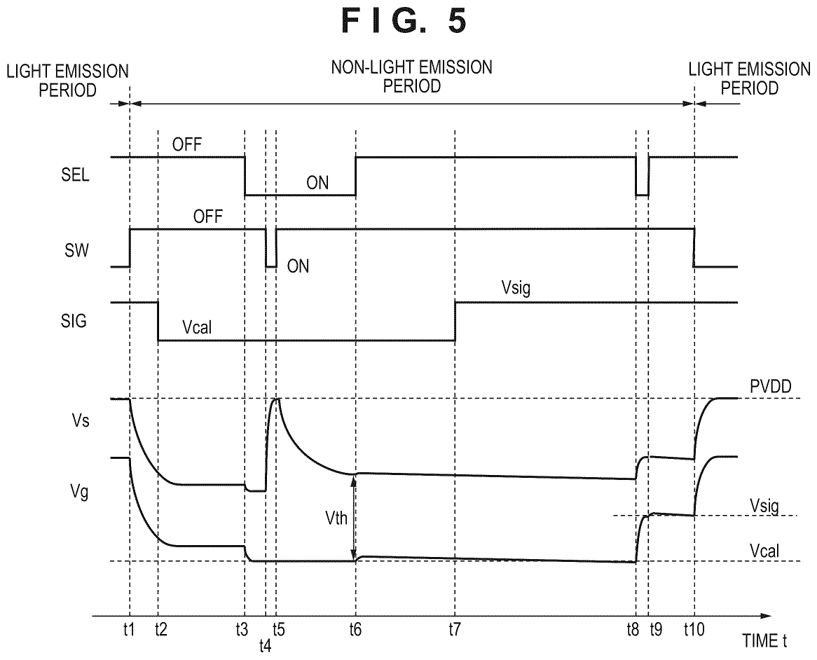

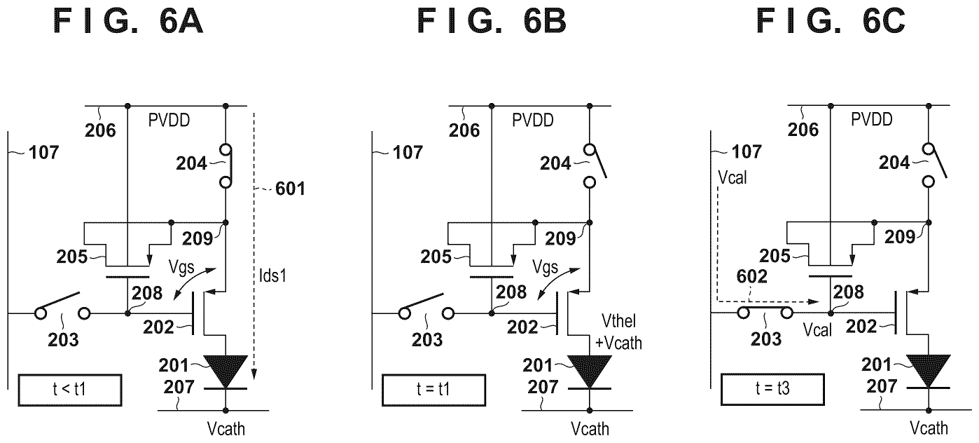

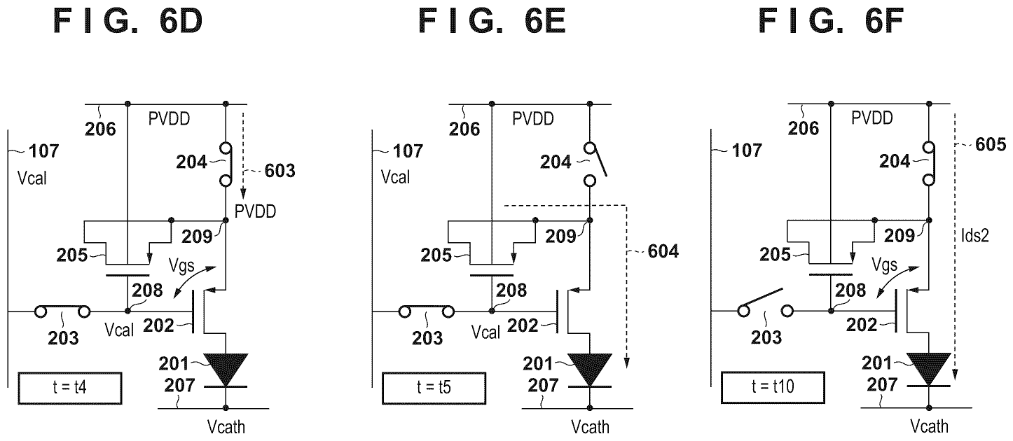

With reference to FIGS. 5 to 6F, an example of the operation of the light emitting device 100 will be described. The timing chart of FIG. 5 shows the waveform of each of the write scanning signal SEL, the light emission scanning signal SW, and the pixel signal SIG, and the change of each of a source potential Vs of the driving transistor 202 and a gate potential Vg of the driving transistor 202. The gate potential Vg is equal to the potential of the node 208. The source potential Vs is equal to the potential of the node 209. For the sake of simplicity, the writing transistor 203 and the switching transistor 204 are represented by switch symbols in FIGS. 6A to 6F. The writing transistor 203 is in the ON state (that is, conductive state) when the write scanning signal SEL is at low level, and is in the OFF state (that is, non-conductive state) when the write scanning signal SEL is at high level. The switching transistor 204 is in the ON state when the light emission scanning signal SW is at low level, and is in the OFF state when the light emission scanning signal SW is at high level.

In the example shown in FIG. 5, one frame period ends at time t1, and the next frame period starts from time t1. One frame period includes a light emission period during which the light emitting element 201 emits light, and a non-light emission period during which the light emitting element 201 emits no light. One frame period may start with the non-light emission period. In the example shown in FIG. 5, the light emission period of one frame period ends at time t1. The length from time t1 to each of time t2 to time t10 may have a value set in advance.

Before time t1, the switching transistor 204 is in the ON state because the light emission scanning signal SW is at low level. Further, the writing transistor 203 is in the OFF state because the write scanning signal SEL is at high level. As a result, as indicated by an arrow 601 in FIG. 6A, a driving current Ids1 corresponding to a gate-source voltage Vgs of the driving transistor 202 is supplied from the power supply line 206 to the light emitting element 201 via the driving transistor 202. The light emitting element 201 emits light with a luminance corresponding to the current value of the driving current Ids1.

At time t1, the light emission scanning circuit 105 switches the light emission scanning signal SW from low level to high level to turn off the switching transistor 204 as shown in FIG. 6B. As a result, no current is supplied from the power supply line 206 to the light emitting element 201 and the light emitting element 201 is turned off. Since no current is supplied to the light emitting element 201, the anode potential of the light emitting element 201 converges to the sum of a threshold voltage Vthel and the cathode potential Vcath of the light emitting element 201 (that is, Vthel+Vcath). At time t1, the writing transistor 203 and the switching transistor 204 remain in the OFF state.

At time t2, the signal output circuit 104 switches the value of the pixel signal SIG to the reference potential Vcal. The supply cycle of the reference potential Vcal defines the horizontal period.

At time t3, the write scanning circuit 103 switches the write scanning signal SEL from high level to low level to turn on the writing transistor 203 as shown in FIG. 6C. As a result, as indicated by an arrow 602, the reference potential Vcal supplied to the signal line 107 is written in the gate of the driving transistor 202 via the writing transistor 203.

At time t4, the light emission scanning circuit 105 switches the light emission scanning signal SW from high level to low level to turn on the switching transistor 204 as shown in FIG. 6D. As a result, the source potential Vs of the driving transistor 202 becomes equal to the power supply potential PVDD. As a result, the gate-source voltage Vgs of the driving transistor 202 at this point of time (that is, |Vcal−PVDD|) is held by the capacitance 401 of the holding transistor 205.

At time t5, the light emission scanning circuit 105 switches the light emission scanning signal SW from low level to high level to turn off the switching transistor 204 as shown in FIG. 6E. As a result, as indicated by an arrow 604, a current flows from the holding transistor 205 to the light emitting element 201 via the driving transistor 202. As a result, as shown in FIG. 5, the gate potential Vg of the driving transistor 202 is maintained at the reference potential Vcal, but the source voltage Vs of the driving transistor 202 drops from the power supply potential PVDD. With this, the gate-source voltage Vgs of the driving transistor 202 decreases and converges to the threshold voltage of the driving transistor 202 as time elapses.

At time t6, the write scanning circuit 103 switches the write scanning signal SEL from low level to high level to turn off the writing transistor 203. As a result, the gate-source voltage Vgs of the driving transistor 202 at this point of time (that is, the threshold voltage of the driving transistor 202) is held by the capacitance 401 of the holding transistor 205.

The operation performed from time t5 to time t6 is an operation for correcting the variation of the threshold voltage of the driving transistor 202 among the plurality of pixel circuits 101, so that this can be called a threshold voltage correction operation. The operation performed from time t3 to time t5 is an operation for preparing for the threshold voltage correction operation, so that this may be called a correction preparation operation. The length of the period of the threshold voltage correction operation (that is, the length from time t5 to time t6) may be the length required for the gate-source voltage Vgs of the driving transistor 202 to sufficiently converge to the threshold voltage of the driving transistor 202. For example, the period of the threshold voltage correction operation may be longer than the period during which both the writing transistor 203 and the switching transistor 204 are set in the ON state (that is, the length from time t4 to time t5).

In order to properly execute the threshold voltage correction operation, the value of the reference potential Vcal may be set such that the gate-source voltage Vgs of the driving transistor 202 at time t5 (that is, |Vcal−PVDD|) is higher than a threshold voltage Vth of the driving transistor 202.

Since a current flows to the light emitting element 201 due to the correction preparation operation and the threshold voltage correction operation, the light emitting element 201 emits light. However, by setting the length of each of the correction preparation operation and the threshold voltage correction operation to be sufficiently short with respect to one frame period, the influence of such light emission can be reduced.

At time t7, the signal output circuit 104 switches the value of the pixel signal SIG to the signal potential Vsig. At time t8, the write scanning circuit 103 switches the write scanning signal SEL from high level to low level to turn on the writing transistor 203. As a result, the signal potential Vsig supplied to the signal line 107 is written in the gate of the driving transistor 202 via the writing transistor 203. With this, the gate-source voltage Vgs of the driving transistor 202 changes. Letting C1 be the capacitance value of the capacitance 401 and C2 be the capacitance value of the capacitance 402, the change amount of the gate-source voltage Vgs is given by C2×(Vsig−Vcal)/(C1+C2).

At time t9, the write scanning circuit 103 switches the write scanning signal SEL from low level to high level to turn off the writing transistor 203. As a result, the gate-source voltage Vgs of the driving transistor 202 at this point of time is held by the capacitance 401 of the holding transistor 205.

At time t10, the light emission scanning circuit 105 switches the light emission scanning signal SW from high level to low level to turn on the switching transistor 204 as shown in FIG. 6F. With this, the driving transistor 202 can supply a current from the power supply line 206 to the light emitting element 201. More specifically, as indicated by an arrow 605, a driving current Ids2 corresponding to the gate-source voltage Vgs of the driving transistor 202 is supplied from the power supply line 206 to the light emitting element 201 via the driving transistor 202. Accordingly, the light emitting element 201 emits light with a luminance corresponding to the current value of the driving current Ids2.

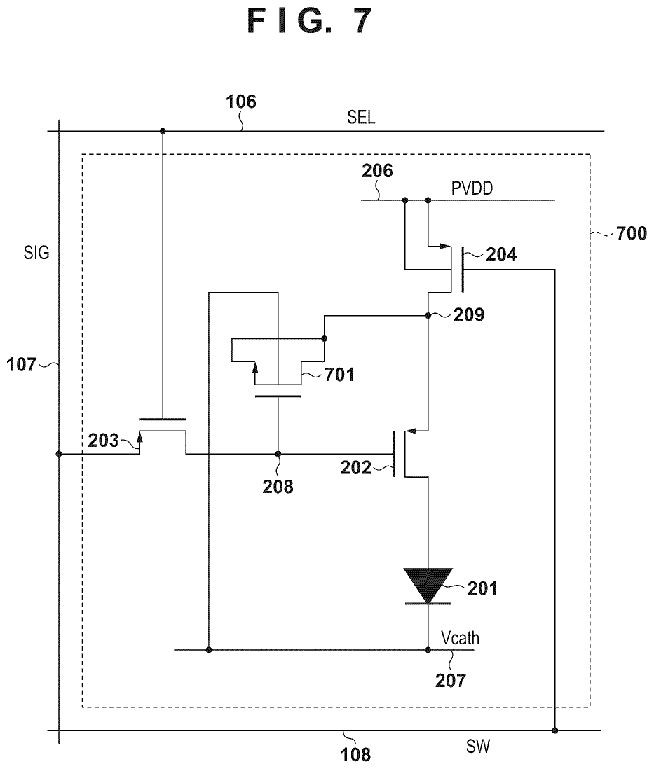

In the pixel circuit 101 described above, the conductivity type of the holding transistor 205 may be the same as the conductivity type of the driving transistor 202 (for example, both may be p-channel). The effect of this arrangement will be described below. FIG. 7 shows a circuit diagram of a pixel circuit 700 including an n-channel holding transistor 701 instead of the p-channel holding transistor 205. The back gate of the holding transistor 701 is connected to the power supply line 207. Accordingly, the capacitance of the holding transistor 701 is connected between the power supply line 207 and the node 209. With this arrangement, for example, in the light emission period, noise from the power supply line 207 may be input to the gate of the driving transistor 202 via the capacitance of the holding transistor 701. As a result, degradation of image quality such as unevenness or shading may occur. On the other hand, in the pixel circuit 101, the capacitance 402 of the holding transistor 205 is connected between the node 209 and the power supply line 206, so such degradation of image quality does not occur.

Furthermore, all of the plurality of transistors included in the pixel circuit 101 may be transistors of the same conductivity type (for example, p-type transistors). This can reduce the number of steps of the manufacturing process of the light emitting device 100, thereby implementing cost reduction.

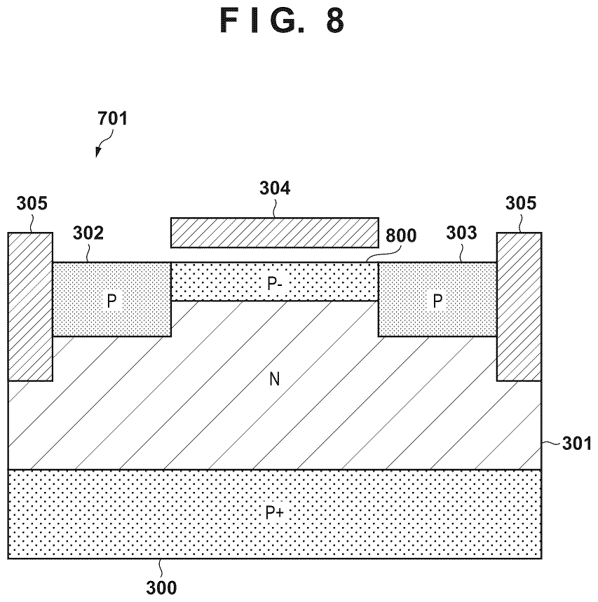

The holding transistor 205 and the driving transistor 202 may be formed such that the threshold voltage of the holding transistor 205 is lower than the threshold voltage of the driving transistor 202. With this, even if the gate-source voltage Vgs of the driving transistor 202 is low (for example, in a case of low tone display), a channel 800 is formed in the capacitance transistor 205 as shown in FIG. 8. If the channel 800 is formed in the holding transistor 205, the values of the capacitances 401 and 402 of the holding transistor 205 increase. Therefore, for example, in a case of low tone display such as black display, the gate potential Vg of the driving transistor 202 becomes less susceptible to the leakage of the writing transistor 203. As a result, uniform image quality with less luminance variation can be obtained.

In order to implement the relationship between the threshold voltages as described above, the holding transistor 205 and the driving transistor 202 may be formed such that the channel concentration of the holding transistor 205 is higher than the channel concentration of the driving transistor 202. The channel concentration may be the impurity concentration of the region where a channel (for example, the channel 800 in FIG. 8) is formed.

Instead of or in addition to implementation due to the difference in the channel concentration, the relationship between the threshold voltages described above may be implemented by another method. For example, in order to implement the relationship between the threshold voltages as described above, the holding transistor 205 and the driving transistor 202 may be formed such that the conductivity type of the gate of the holding transistor 205 is different from the conductivity type of the gate of the driving transistor 202. With this, the threshold voltage increases by the difference in work function, and the threshold voltage of the holding transistor 205 becomes lower than the threshold voltage of the driving transistor 202. More specifically, the conductivity type (polarity) of the gate of the holding transistor 205 may be p-type, and the conductivity type (polarity) of the gate of the driving transistor 202 may be n-type. The relationship between the threshold voltages described above may be implemented by a method different from the above-described examples.

The holding transistor 205 may be formed on the same semiconductor substrate as the driving transistor 202. Instead, the holding transistor 205 may be formed on a semiconductor substrate different from the driving transistor 202. When the holding transistor 205 is formed on a semiconductor substrate different from the driving transistor 202, the area of each of the driving transistor 202 and the holding transistor 205 can be increased. In general, as the area of a transistor increases, its characteristic variation tends to decrease. That is, by increasing the area of the driving transistor 202, its characteristic variation can be decreased. Furthermore, by increasing the area of the holding transistor 205, the values of the capacitances 401 and 402 of the holding transistor 205 can be increased. As a result, for example, in a case of low tone display such as black display, the gate potential of the driving transistor 202 becomes less susceptible to the influence of the leakage of the writing transistor 203, and the image quality improves.

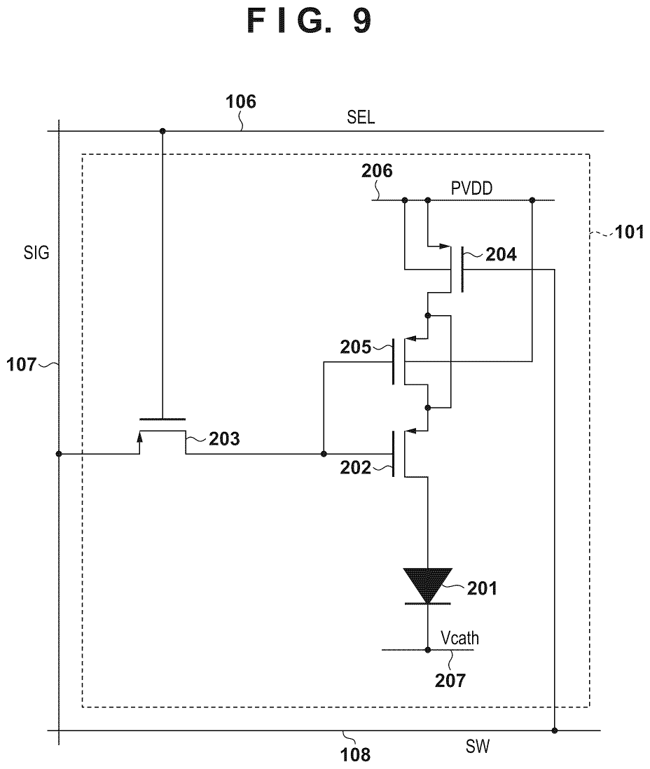

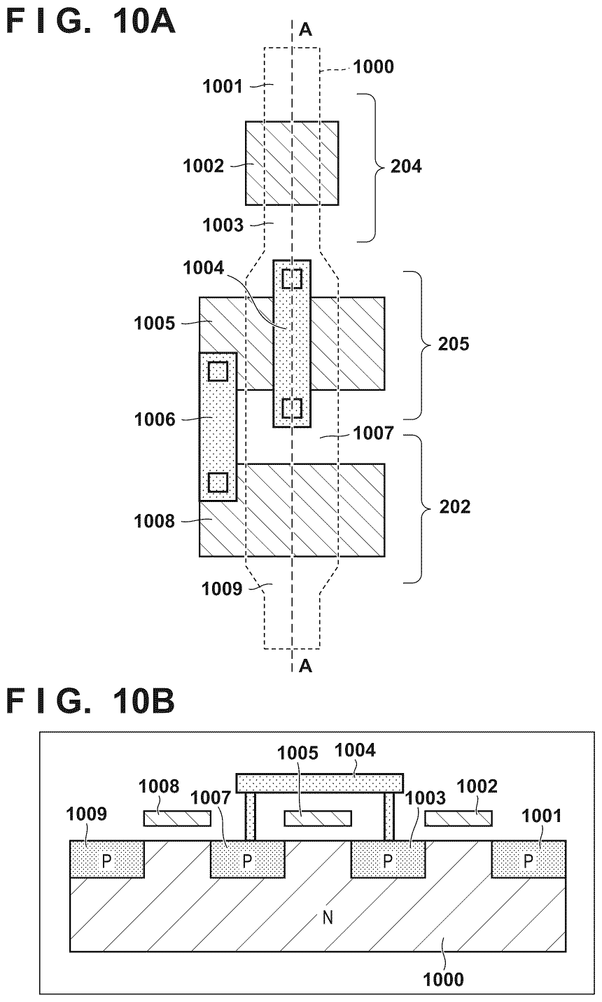

FIG. 9 is a circuit diagram in which the transistors included in the pixel circuit 101 are respectively arranged at positions corresponding to the layout. With reference to FIGS. 10A and 10B, a layout example of the switching transistor 204, the holding transistor 205, and the driving transistor 202 will be described. FIG. 10A shows a plan view including these transistors, and FIG. 10B shows a sectional view taken along a line A-A in FIG. 10A. As shown in FIGS. 10A and 10B, the switching transistor 204, the holding transistor 205, and the driving transistor 202 may be formed in the same active region 1000. This can improve the layout efficiency of these transistors and increase the resolution of the light emitting device 100.

More specifically, four impurity regions 1001, 1003, 1007, and 1009 are formed in the active region 1000. Three gate electrodes 1002, 1005, and 1008 are formed to partially cover the active region 1000. A gate insulating film (not shown) is formed between each gate electrode and the active region 1000. The impurity region 1003 and the impurity region 1007 are electrically connected by a conductive member 1004. The gate electrode 1005 and the gate electrode 1008 are electrically connected by a conductive member 1006.

The impurity region 1001 functions as the source of the switching transistor 204. The gate electrode 1002 functions as the gate of the switching transistor 204. The impurity region 1003 functions as the drain of the switching transistor 204 and the source of the holding transistor 205. The gate electrode 1005 functions as the gate of the holding transistor 205. The impurity region 1007 functions as the drain of the holding transistor 205 and the source of the driving transistor 202. The gate electrode 1008 functions as the gate of the driving transistor 202. The impurity region 1009 functions as the drain of the driving transistor 202.

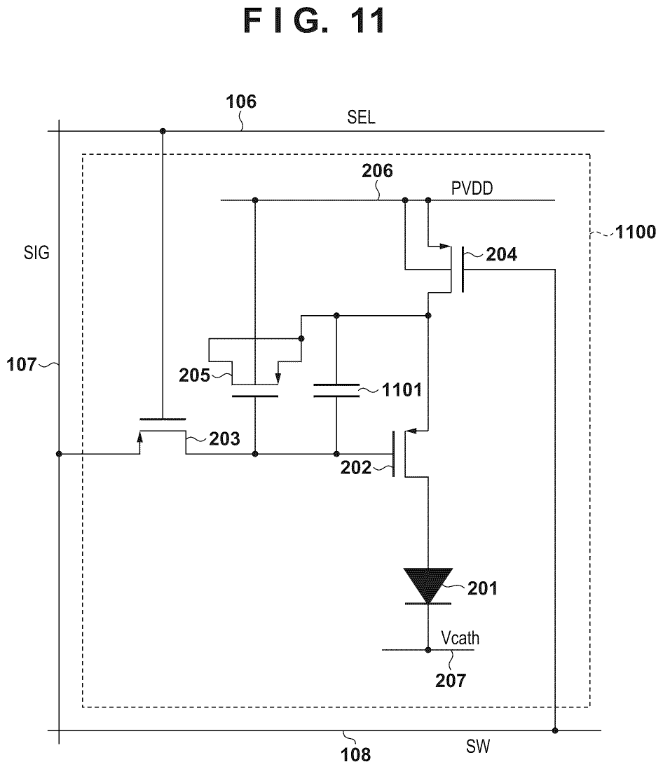

With reference to FIG. 11, a pixel circuit 1100 as a modification of the pixel circuit 101 described above will be described. The pixel circuit 1100 is different from the pixel circuit 101 in that a capacitive element 1101 is further included. The rest may be the same as in the pixel circuit 101. The capacitive element 1101 connects the gate of the driving transistor 202 and the source of the driving transistor 202. The capacitive element 1101 may have, for example, a MIM (Metal-Insulator-Metal) structure. The capacitive element 1101 may be formed on the same semiconductor substrate as the driving transistor 202, or may be formed on another semiconductor substrate. By further including the capacitive element 1101, the value of the capacitance between the gate and source of the driving transistor 202 can be increased. As a result, for example, a change in gate potential of the driving transistor 202 caused by the leakage of the writing transistor 203 in the light emission period can be decreased, and the image quality improves.

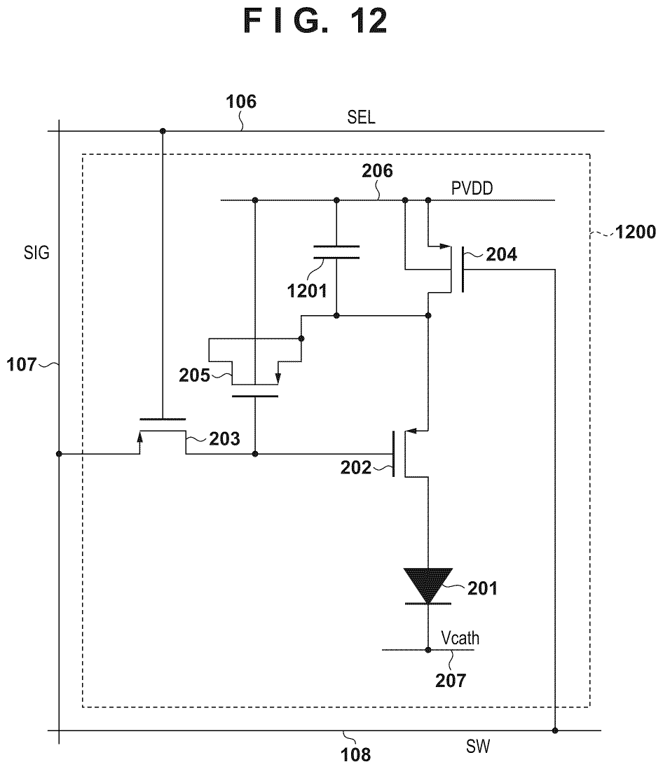

With reference to FIG. 12, a pixel circuit 1200 as a modification of the pixel circuit 101 described above will be described. The pixel circuit 1200 is different from the pixel circuit 101 in that a capacitive element 1201 is further included. The rest may be the same as in the pixel circuit 101. The capacitive element 1201 connects the gate of the driving transistor 202 and the power supply line 206. The capacitive element 1201 may have, for example, a MIM structure. The capacitive element 1201 may be formed on the same semiconductor substrate as the driving transistor 202, or may be formed on another semiconductor substrate. By further including the capacitive element 1201, the value of the capacitance between the gate of the driving transistor 202 and the power supply line 206 can be increased. As a result, the fluctuation of the source potential of the driving transistor 202 upon signal writing can be decreased, so that the signal amplitude can be decreased. This implements driving power reduction.

The pixel circuit 1200 may further include the capacitive element 1101 shown in FIG. 11. With this, both the effect obtained by the capacitive element 1101 and the effect obtained by the capacitive element 1201 are implemented.

In the above-described embodiment, the switching transistor 204, the driving transistor 202, and the light emitting element 201 are connected in series such that the driving transistor 202 is arranged on the path between the switching transistor 204 and the light emitting element 201. The connection order of the switching transistor 204, the driving transistor 202, and the light emitting element 201 is not limited to this, and they may be arranged in another order.

According to the above-described embodiment, the capacitance connecting the gate and source of the driving transistor 202 and the capacitance connecting the gate of the driving transistor 202 and the power supply line 206 can be implemented by one holding transistor 205. In this case, since the number of elements included in the pixel circuit 101 can be limited, for example, pixel size reduction and cost reduction can be implemented. In addition, according to the arrangement of the pixel circuit 101 shown in FIG. 2, the threshold voltage correction operation described with reference to FIGS. 5 to 6F can be executed, so that it is possible to reduce the influence of variation of the threshold voltage of the driving transistor 202, and the high resolution light emitting device 100 can be implemented.

### Second Embodiment

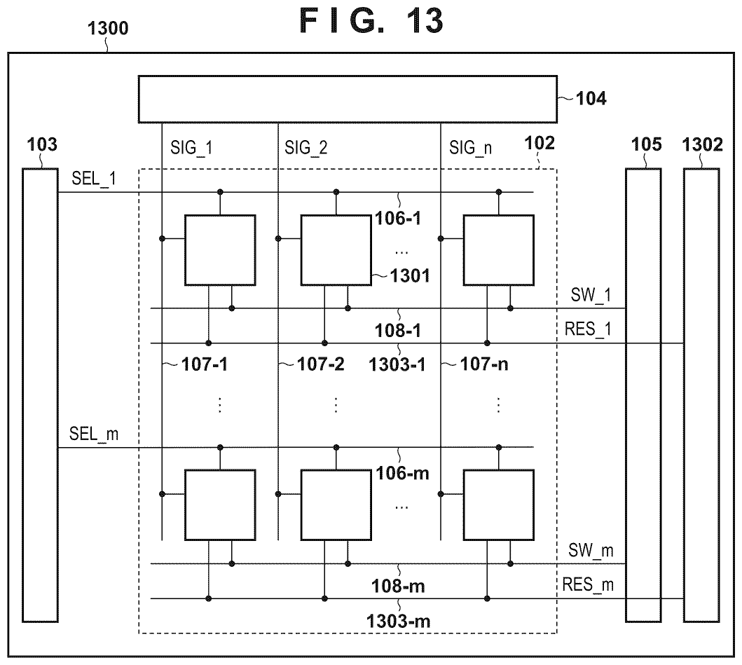

With reference to FIG. 13, an example of the arrangement of a light emitting device 1300 according to the second embodiment will be described. The light emitting device 1300 is different from the light emitting device 100 in that it includes an initialization scanning circuit 1302 and pixel circuits 1301 instead of the pixel circuits 101, and further includes one or more initialization scanning lines 1303-1 to 1303-m. The rest may be the same as in the light emitting device 100.

The initialization scanning circuit 1302 is arranged around a pixel array portion 102. The initialization scanning circuit 1302 is an example of circuits forming the driving unit of the light emitting device 1300. The initialization scanning circuit 1302 forms a scanning driving system together with a write scanning circuit 103 and a light emission scanning circuit 105. In the layout shown in FIG. 13, the initialization scanning circuit 1302 is arranged on the right side of the pixel array portion 102. Instead, another layout may be used. For example, the initialization scanning circuit 1302 may be arranged on the left side of the pixel array portion 102. Alternatively, a layout may be used in which the initialization scanning circuit 1302 is arranged on each of the left and right sides of the pixel array portion 102.

In the pixel array portion 102, m initialization scanning lines 1303-1 to 1303-m are arranged along pixel rows. The m initialization scanning lines 1303-1 to 1303-m are collectively referred to as initialization scanning lines 1303. One initialization scanning line 1303 may be arranged for one pixel row.

The initialization scanning line 1303 is connected to the corresponding output terminal of m output terminals of the initialization scanning circuit 1302. The initialization scanning circuit 1302 is formed by a shift register, which sequentially shifts a start pulse in synchronization with a clock pulse, or the like. The initialization scanning circuit 1302 supplies initialization signals RES_1 to RES_m (to be collectively referred to as initialization signals RES) to the anodes of light emitting elements 201 in synchronization with line sequential scanning by the write scanning circuit 103. The initialization signal RES is used to initialize the potential of the anode of the light emitting element 201.

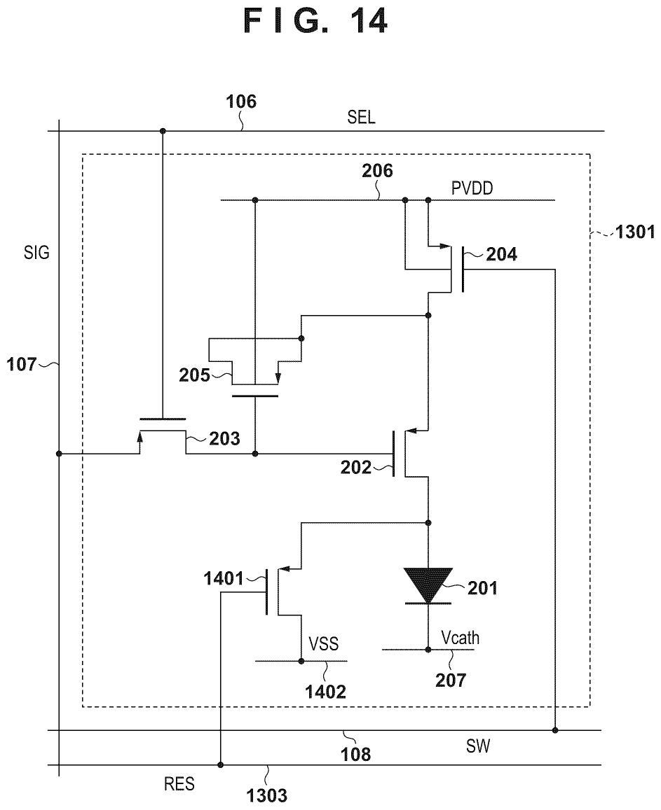

With reference to FIG. 14, an example of the arrangement of the pixel circuit 1301 will be described. The pixel circuit 1301 is different from the pixel circuit 101 in that an initialization transistor 1401 and a power supply line 1402 are further included. The rest may be the same as in the pixel circuit 101.

The initialization transistor 1401 is arranged on a path connecting the drain of a driving transistor 202 and the power supply line 1402. In the example shown in FIG. 14, the initialization transistor 1401 is a p-channel transistor. Instead, the initialization transistor 1401 may be an n-channel transistor.

One (for example, source) of two main terminals of the initialization transistor 1401 is connected to the drain of the driving transistor 202. The other (for example, drain) of two main terminals of the initialization transistor 1401 is connected to the power supply line 1402. The gate of the initialization transistor 1401 is connected to the initialization scanning line 1303.

A negative power supply potential VSS is supplied to the power supply line 1402. Let Vthel be the threshold voltage of the light emitting element 201, and Vcath be the power supply potential supplied to the power supply line 207 connected to the cathode of the light emitting element 201. In this case, the power supply potential VSS is set to satisfy a condition of VSS<Vthel+Vcath. With this, while the initialization transistor 1401 is in the conductive state, a reverse vias is applied to the light emitting element 201. The power supply potential VSS may have the value same as or different from the value of the power supply potential Vcath. If the power supply potential VSS and the power supply potential Vcath have the same value, the power supply line 207 can be used instead of the power supply line 1402. This can reduce the number of wirings.

Before the timing of inputting a signal potential Vsig to the gate of the driving transistor 202, the initialization scanning circuit 1302 turns on the initialization transistor 1401 to write the power supply potential VSS in the anode of the light emitting element 201. With this, the anode of the light emitting element 201 is set to VSS during a threshold voltage correction operation, so no current flows to the light emitting element 201 during the threshold voltage correction operation. As a result, a phenomenon such as so-called fading of a black color does not occur during black image display, and satisfactory contrast can be obtained.

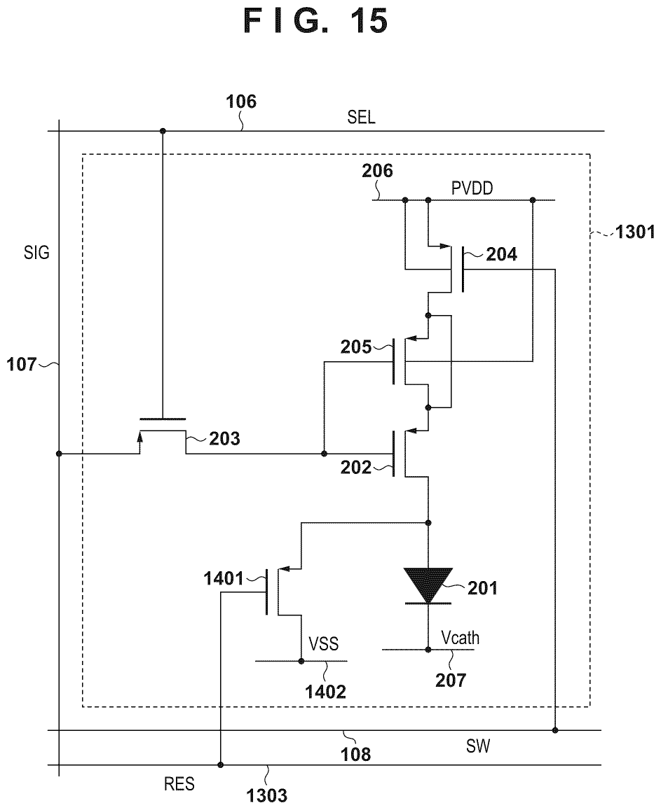

FIG. 15 is a circuit diagram in which transistors included in the pixel circuit 1301 are respectively arranged at positions corresponding to the layout. With reference to FIG. 16, a layout example of a switching transistor 204, a holding transistor 205, the driving transistor 202, and the initialization transistor 1401 will be described. FIG. 15 shows a plan view including these transistors. A sectional view including these transistors will be omitted since it can be analogized from FIG. 10B.

As shown in FIG. 16, the switching transistor 204, the holding transistor 205, the driving transistor 202, and the initialization transistor 1401 may be formed in the same active region 1000. This can improve the layout efficiency of these transistors and increase the resolution of the light emitting device 1300.

More specifically, in addition to four impurity regions 1001, 1003, 1007, and 1009, an impurity region 1601 is formed in the active region 1000. Further, in addition to three gate electrodes 1002, 1005, and 1008, a gate electrode 1600 is formed to partially cover the active region 1000. The impurity region 1009 functions as the drain of the driving transistor 202 and the source of the initialization transistor 1401. The gate electrode 1600 functions as the gate of the initialization transistor 1401. The impurity region 1601 functions as the drain of the initialization transistor 1401.

Also in the second embodiment, as in the first embodiment, the pixel circuit 1301 may include one or both of capacitive elements 1101 and 1201. Also in the second embodiment, as in the first embodiment, the switching transistor 204, the driving transistor 202, and the light emitting element 201 may be arranged in another order.

The second embodiment can also reduce the number of elements included in the pixel circuit having the initialization function of the light emitting element 201.

### OTHER EMBODIMENTS

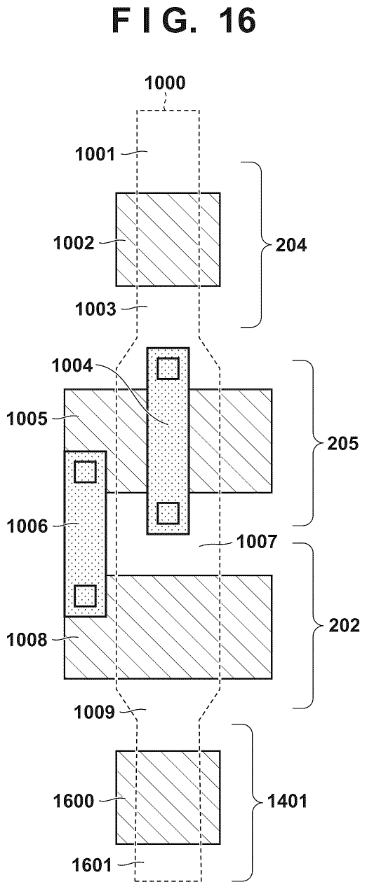

FIG. 17 is a schematic view showing an example of a display device according to this embodiment. A display device 1700 may include, between an upper cover 1701 and a lower cover 1709, a touch panel 1703, a display panel 1705, a frame 1706, a circuit board 1707, and a battery 1708. The touch panel 1703 and the display panel 1705 are connected to flexible printed circuit FPCs 1702 and 1704, respectively. Transistors are printed on the circuit board 1707. The battery 1708 may not be provided if the display device is not a portable apparatus, or may be provided in another position even if the display device is a portable apparatus.

The display device according to this embodiment may include color filters of red, green, and blue. The color filters of red, green, and blue may be arranged in a delta array.

The display device according to this embodiment may also be used for a display unit of a portable terminal. At this time, the display unit may have both a display function and an operation function. Examples of the portable terminal are a portable phone such as a smartphone, a tablet, and a head mounted display.

The display device according to this embodiment may be used for a display unit of an image capturing device including an optical unit having a plurality of lenses, and an image sensor for receiving light having passed through the optical unit. The image capturing device may include a display unit for displaying information acquired by the image sensor. In addition, the display unit may be either a display unit exposed outside the image capturing device, or a display unit arranged in the finder. The image capturing device may be a digital camera or a digital video camera.

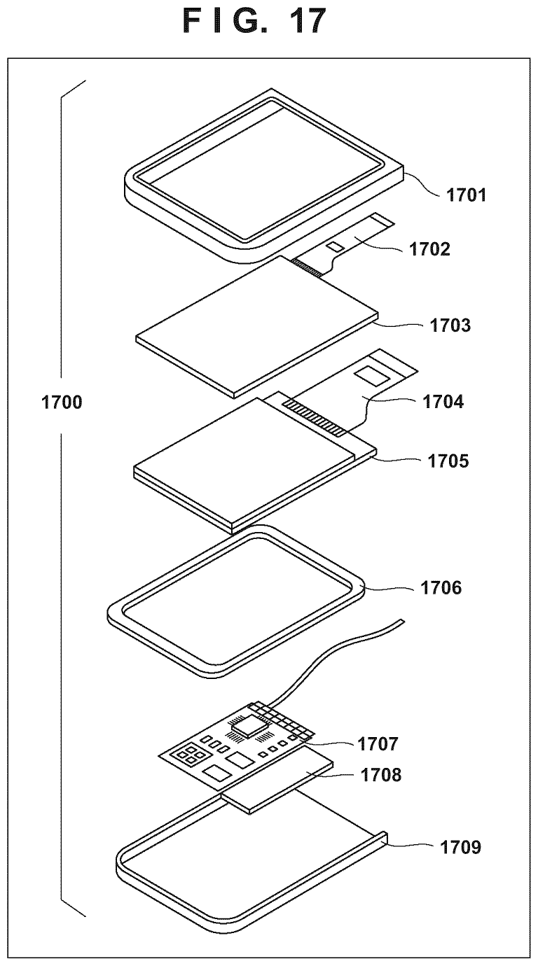

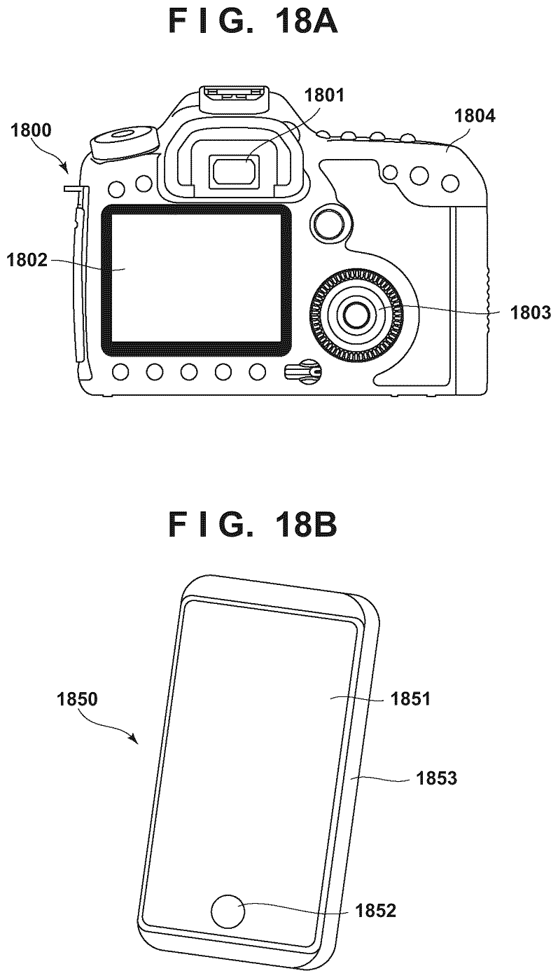

FIG. 18A is a schematic view showing an example of an image capturing device according to this embodiment. An image capturing device 1800 may include a viewfinder 1801, a rear display 1802, an operation unit 1803, and a housing 1804. The viewfinder 1801 may include the display device according to this embodiment. In this case, the display device may display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time, so the information is preferably displayed as soon as possible. Therefore, the display device using the organic light emitting element of the present invention is preferably used. This is so because the organic light emitting element has a high response speed. The display device using the organic light emitting element can be used for the apparatuses that require a high display speed more preferably than for the liquid crystal display device.

The image capturing device 1800 includes an optical unit (not shown). This optical unit includes a plurality of lenses, and forms an image on an image sensor that is accommodated in the housing 1804. The focal points of the plurality of lenses can be adjusted by adjusting the relative positions. This operation can also automatically be performed. The image capturing device may be called a photoelectric conversion device. Instead of sequentially capturing an image, the photoelectric conversion device can include, as an image capturing method, a method of detecting the difference from a previous image, a method of extracting an image from an always recorded image, or the like.

FIG. 18B is a schematic view showing an example of an electronic apparatus according to this embodiment. An electronic apparatus 1850 includes a display unit 1851, an operation unit 1852, and a housing 1853. The housing 1853 may accommodate a circuit, a printed board including this circuit, a battery, and a communication unit. The operation unit 1852 may be a button or a touch-panel-type reaction unit. The operation unit may also be a biometric authentication unit that performs unlocking or the like by authenticating a fingerprint. The electronic apparatus including the communication unit can also be regarded as a communication apparatus. The electronic apparatus may further have a camera function by including a lens and an image sensor. An image captured by the camera function is displayed on the display unit. Examples of the electronic apparatus are a smartphone and a laptop computer.

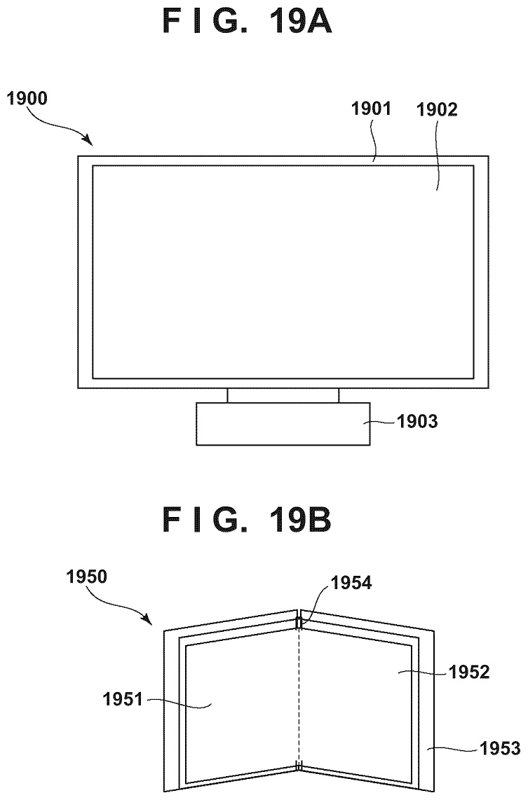

FIGS. 19A and 19B are schematic views showing examples of a display device according to this embodiment. FIG. 19A shows a display device such as a television monitor or a PC monitor. A display device 1900 includes a frame 1901 and a display unit 1902. The light emitting device according to the embodiment may be used in the display unit 1902.

The display device 1900 includes a base 1903 that supports the frame 1901 and the display unit 1902. The base 1903 is not limited to the form shown in FIG. 19A. The lower side of the frame 1901 may also function as the base.

In addition, the frame 1901 and the display unit 1902 may be bent. The radius of curvature may be 5,000 mm (inclusive) to 6,000 mm (inclusive).

FIG. 19B is a schematic view showing another example of the display device according to this embodiment. A display device 1950 shown in FIG. 19B is configured to be foldable, that is, the display device 1950 is a so-called foldable display device. The display device 1950 includes a first display unit 1951, a second display unit 1952, a housing 1953, and a bending point 1954. Each of the first display unit 1951 and the second display unit 1952 may include the light emitting device according to the embodiment. The first display unit 1951 and the second display unit 1952 may also be one seamless display device. The first display unit 1951 and the second display unit 1952 can be divided by the bending point. The first display unit 1951 and the second display unit 1952 may display different images, and may display one image together.

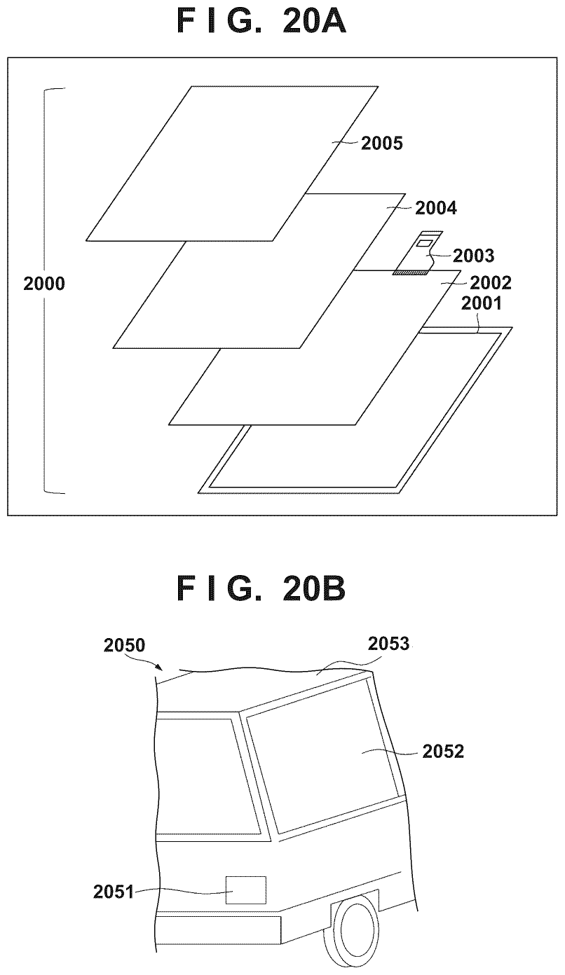

FIG. 20A is a schematic view showing an example of an illumination device according to this embodiment. An illumination device 2000 may include a housing 2001, a light source 2002, a circuit board 2003, an optical film 2004, and a light-diffusing unit 2005. The light source may include the organic light emitting element according to the embodiment. The optical film may be a film that improves the color rendering of the light source. When performing lighting-up or the like, the light-diffusing unit can throw the light of the light source over a broad range by effectively diffusing the light. The optical film and the light-diffusing unit may be provided on the illumination light emission side. The illumination device may also include a cover on the outermost portion, as needed.

The illumination device is, for example, a device for illuminating the interior of the room. The illumination device may emit white light, natural white light, or light of another color from blue to red. The illumination device may include a light control circuit for controlling these light components. The illumination device may include the organic light emitting element according to the present invention and a power supply circuit connected to the organic light emitting element. The power supply circuit is a circuit for converting an AC voltage into a DC voltage. White has a color temperature of 4,200 K, and natural white has a color temperature of 5,000 K. The illumination device may also include a color filter.

In addition, the illumination device according to this embodiment may include a heat radiation unit. The heat radiation unit radiates the internal heat of the device to the outside of the device, and examples are a metal having a high specific heat and liquid silicon.

FIG. 20B is a schematic view of an automobile as an example of a moving body according to this embodiment. The automobile has a taillight as an example of the lighting appliance. An automobile 2050 has a taillight 2051, and may have a form in which the taillight is turned on when performing a braking operation or the like.

The taillight 2051 may include the organic light emitting element according to the embodiment. The taillight may include a protection member for protecting the organic EL element. The material of the protection member is not limited as long as the material is a transparent material with a strength that is high to some extent, and is preferably polycarbonate or the like. A furandicarboxylic acid derivative, an acrylonitrile derivative, or the like may be mixed in polycarbonate.

The automobile 2050 may include a vehicle body 2053, and a window 2052 attached to the vehicle body 2053. The window may be a transparent display as long as it is not a window for checking the front or rear of the automobile. This transparent display may include the organic light emitting element according to the embodiment. In this case, the constituent materials of the electrodes and the like of the organic light emitting element are formed from transparent members.

The moving body according to this embodiment includes a driving unit such as an engine or a motor and a moving unit such as wheels, a propeller, or tires. For example, the moving body may be an automobile, a ship, an airplane, a drone, a bicycle, a railroad car, or the like. The moving body may include a main body and a lighting appliance provided on the main body. The lighting appliance may emit light for making a notification of the position of the main body. The lighting appliance includes the organic light emitting element according to the embodiment.

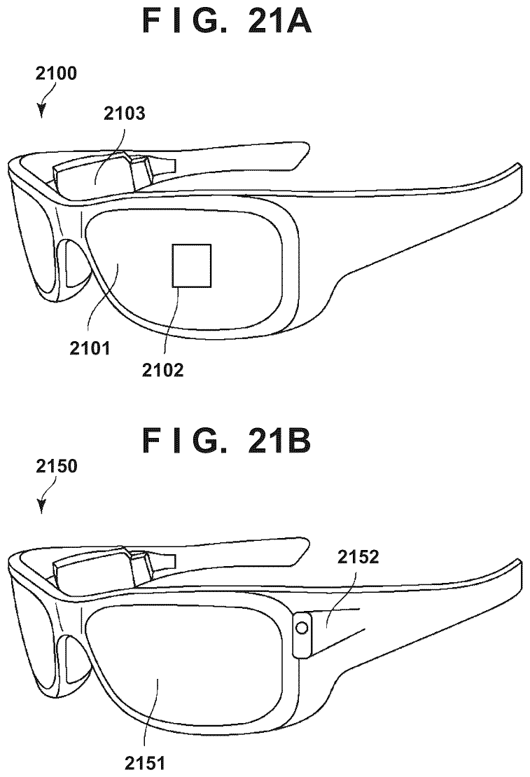

An application example of the display device according to each embodiment described above will be described with reference to FIGS. 21A and 21B. The display device can be applied to a system that can be worn as a wearable device such as smartglasses, an HMD, or a smart contact lens. An image capturing display device used in such an application example includes an image capturing device capable of photoelectrically converting visible light and a display device capable of emitting visible light.

Glasses 2100 (smartglasses) according to one application example will be described with reference to FIG. 21A. An image capturing device 2102 such as a CMOS sensor or an SPAD is provided on the surface side of a lens 2101 of the glasses 2100. In addition, the display device of each of the above-described embodiments is provided on the back surface side of the lens 2101.

The glasses 2100 further includes a control device 2103. The control device 2103 functions as a power supply that supplies power to the image capturing device 2102 and the display device according to each embodiment. In addition, the control device 2103 controls the operations of the image capturing device 2102 and the display device. An optical system configured to condense light to the image capturing device 2102 is formed on the lens 2101.

Glasses 2150 (smartglasses) according to one application example will be described with reference to FIG. 21B. The glasses 2150 includes a control device 2152. An image capturing device corresponding to the image capturing device 2102 and a display device are mounted on the control device 2152. An optical system configured to project light emitted from the display device in the control device 2152 is formed in a lens 2151, and an image is projected to the lens 2151. The control device 2152 functions as a power supply that supplies power to the image capturing device and the display device, and controls the operations of the image capturing device and the display device. The control device may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The display device according to the embodiment of the present invention may include an image capturing device including a light receiving element, and a displayed image on the display device may be controlled based on the line-of-sight information of the user from the image capturing device.

More specifically, the display device decides a first display region at which the user is gazing and a second display region other than the first display region based on the line-of-sight information. The first display region and the second display region may be decided by the control device of the display device, or those decided by an external control device may be received. In the display region of the display device, the display resolution of the first display region may be controlled to be higher than the display resolution of the second display region. That is, the resolution of the second display region may be lower than that of the first display region.

In addition, the display region includes a first display region and a second display region different from the first display region, and a region of higher priority is decided from the first display region and the second display region based on line-of-sight information. The first display region and the second display region may be decided by the control device of the display device, or those decided by an external control device may be received. The resolution of the region of higher priority may be controlled to be higher than the resolution of the region other than the region of higher priority. That is, the resolution of the region of relatively low priority may be low.

Note that AI may be used to decide the first display region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the display device, the image capturing device, or an external device. If the external device holds the AI program, it is transmitted to the display device via communication.

When performing display control based on line-of-sight detection, smartglasses further including an image capturing device configured to capture the outside can preferably be applied. The smartglasses can display captured outside information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-189527, filed Nov. 6, 2023, which is hereby incorporated by reference herein in its entirety.

What is claimed is:

1. Alight emitting device comprising:
a light emitting element;
a driving transistor and a switching transistor each arranged on a path where a current for causing the light emitting element to emit light flows;
a writing transistor arranged on a path connecting a signal line to which a pixel signal is supplied and a gate of the driving transistor; and
a holding transistor configured to hold a gate-source voltage of the driving transistor,
wherein
a gate of the holding transistor is connected to the gate of the driving transistor,
each of a source and a drain of the holding transistor is connected to a source of the driving transistor,
the holding transistor and the switching transistor are formed in a same impurity region, and
a conductivity type of the holding transistor is the same as a conductivity type of the driving transistor.

2. The device according to claim 1, wherein the driving transistor is arranged on a path connecting the light emitting element and the switching transistor.

3. The device according to claim 1, wherein a threshold voltage of the holding transistor is lower than a threshold voltage of the driving transistor.

4. The device according to claim 3, wherein a channel concentration of the holding transistor is higher than a channel concentration of the driving transistor.

5. The device according to claim 3, wherein a conductivity type of the gate of the holding transistor is different from a conductivity type of the gate of the driving transistor.

6. The device according to claim 1, wherein the switching transistor, the holding transistor, and the driving transistor are formed in a same active region.

7. The device according to claim 1, wherein the holding transistor and the driving transistor are formed on different semiconductor substrates.

8. The device according to claim 1, further comprising a first capacitive element connecting the gate of the driving transistor and the source of the driving transistor.

9. The device according to claim 1, further comprising a second capacitive element connecting the source of the driving transistor and a power supply line.

10. The device according to claim 1, further comprising an initialization transistor arranged on a path connecting a drain of the driving transistor and a power supply line.

11. The device according to claim 10, wherein the switching transistor, the holding transistor, the driving transistor, and the initialization transistor are formed in a same active region.

12. The device according to claim 1, wherein a back gate of the holding transistor and a source of the switching transistor are connected to a same power supply line.

13. A display device comprising a light emitting device according to claim 1, and an active element connected to the light emitting device.

14. A photoelectric conversion device comprising an optical unit including a plurality of lenses, an image sensor configured to receive light having passed through the optical unit, and a display unit configured to display an image,
wherein the display unit displays an image captured by the image sensor, and includes a light emitting device according to claim 1.

15. An electronic apparatus comprising a housing provided with a display unit, and a communication unit provided in the housing and configured to perform external communication,
wherein the display unit includes a light emitting device according to claim 1.

16. An illumination device comprising a light source, and at least one of a light diffusing unit and an optical film,
wherein the light source includes a light emitting device according to claim 1.

17. A moving body comprising a main body, and a lighting appliance provided in the main body,
wherein the lighting appliance includes a light emitting device according to claim 1.
